(19) United States
(12) Patent Application Publication
(10) Pub. No.: US 2025/0212321 A1
(43) Pub. Date: Jun. 26, 2025

(54) SUBSTRATE AND MANUFACTURING METHOD THEREOF

(71) Applicant: Dyi-Chung HU, Hsinchu County (TW)

(72) Inventor: Dyi-Chung HU, Hsinchu County (TW)

(21) Appl. No.: 18/973,071

(22) Filed: Dec. 8, 2024

Related U.S. Application Data
(60) Provisional application No. 63/613,012, filed on Dec. 20, 2023.
(60) Provisional application No. 63/555,082, filed on Feb. 18, 2024.

(51) Int. Cl. H05K 1/02; H05K 1/03; H05K 3/00; H05K 3/28

(52) U.S. Cl. CPC H05K 1/0271; H05K 1/0306; H05K 3/0044; H05K 3/285; H05K 2201/068; H05K 2201/09145; H05K 2201/09827; H05K 2203/025; H05K 2203/1338

(57) ABSTRACT

A substrate includes a core layer, a first circuit structure, a second circuit structure, a first protection layer, and second protection layer. The core layer includes a top surface, a bottom surface, and a rounded edge located between the top surface and the bottom surface. The first circuit structure is disposed on the top surface. The second circuit structure is disposed on the bottom surface. The first protection layer is disposed on and directly in contact with the rounded edge portion. The second protection layer, wherein the first protection layer is enclosed by the second protection layer. A manufacturing method of a substrate is also provided.

### CROSS-REFERENCE TO RELATED APPLICATION

This application claims the priority benefit of the U.S. provisional application Ser. No. 63/613,012, filed on Dec. 20, 2023, and the priority benefit of the U.S. provisional application Ser. No. 63/555,082, filed on Feb. 18, 2024. The entirety of each of the above-mentioned patent applications is hereby incorporated by reference herein and made a part of this specification.

### BACKGROUND

### Technical Field

The disclosure is related to a substrate and manufacturing method thereof.

### Description of Related Art

In order to meet the needs of the product for better reliability, the design of substrate has become a challenge to researchers in the field. For example, improving the crack issue in the edge of the substrate to enhance the glass substrate reliability. It becomes a critical issue when realizing that glass is a core material.

### SUMMARY

This disclosure provides a substrate and manufacturing method thereof, which can improve the reliability of a subsequent product.

A substrate includes a core layer, a first circuit structure, a second circuit structure and a first protection layer. The core layer includes a top surface, a bottom surface, and a rounded edge located between the top surface and the bottom surface. The first circuit structure is disposed on the top surface. The second circuit structure is disposed on the bottom surface. The first protection layer is disposed on and directly in contact with the rounded edge portion. A coefficient of thermal expansion of a material of the first protection layer is higher than a coefficient of thermal expansion of a material of the core layer.

A manufacturing method of a substrate includes: providing a core layer; forming a first circuit structure on a top surface of the core layer; forming a second circuit structure on a bottom surface of the core layer; patterning the first circuit structure and the second circuit structure; forming a rounded edge portion between the top surface and the bottom surface of the core layer; and performing a deposition process on the rounded edge portion to form a first protection layer, wherein the rounded edge portion is compressed by the first protection layer.

A substrate includes a glass core layer and a protection layer. The glass core layer includes a plurality of rough portions. The protection layer is disposed on and directly in contact with the plurality of rough portions. A coefficient of thermal expansion of a material of the protection layer is higher than a coefficient of thermal expansion of a material of the glass core layer.

Based on the above, cracks of the core layer may be suppressed by the protection layer, thereby the probability of propagation may be reduced which may improve reliability of a subsequent product.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 6 are partial schematic cross-sectional views illustrating a manufacturing method of a substrate according to some embodiments of the disclosure.

FIG. 7 is a partial schematic top view of the structure of FIG. 1.

FIG. 8 is a partial schematic top view of the structure of FIG. 5.

FIG. 9 is partial schematic cross-sectional view illustrating a core layer of a substrate according to some embodiments of the disclosure.

FIG. 10 and FIG. 13 are partial schematic enlarge view of the structure of FIG. 9.

FIG. 11 and FIG. 12 are partial schematic cross-sectional views illustrating a manufacturing method of a core layer of a substrate according to some embodiments of the disclosure following by FIG. 10.

FIG. 14 and FIG. 15 are partial schematic cross-sectional views illustrating a manufacturing method of a core layer of a substrate according to some embodiments of the disclosure following by FIG. 13.

### DESCRIPTION OF THE EMBODIMENTS

Exemplary embodiments of the disclosure are described below comprehensively with reference to the figures, but the disclosure may also be implemented in different ways and should not be construed as limited to the embodiments described herein. In the drawings, for the sake of clarity, the size and thickness of various regions, parts, and layers may not be drawn to actual scale. In order to facilitate understanding, the same elements in the following description are described with the same symbols.

The disclosure is more comprehensively described with reference to the figures of this embodiment. However, the disclosure may also be implemented in various different forms, and is not limited to the embodiments in the present specification. Thicknesses, dimensions, and sizes of layers or regions in the drawings are exaggerated for clarity. The same reference numbers are used in the drawings and the description to indicate the same or like parts, which are not repeated in the following embodiments.

Directional terms (for example, upper, lower, right, left, front, back, top, and bottom) used herein only refer to the graphical use, and are not intended to imply absolute orientation.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion.

Unless otherwise defined, all terms (including technical and scientific terms) used herein have the same meaning as that commonly understood by one of ordinary skill in the art to which this disclosure belongs.

Unless otherwise stated, the term “range from” used in the specification to define a value range is intended to cover a range equal to and between the stated endpoint values. For example, a size range ranges from a first value to a second value means that the size range may cover the first value, the second value, and any value between the first value and the second value.

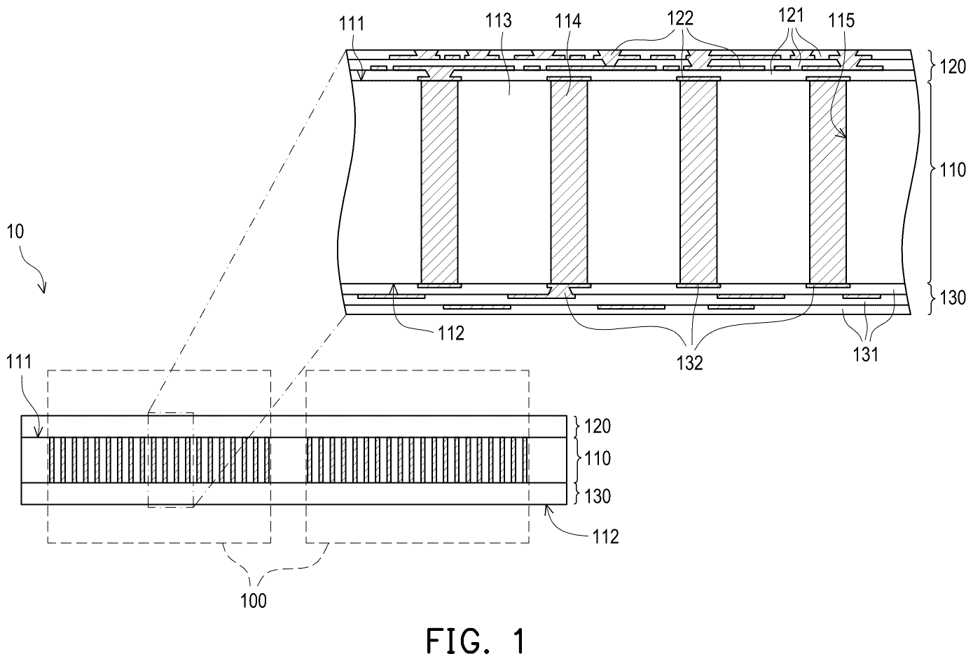

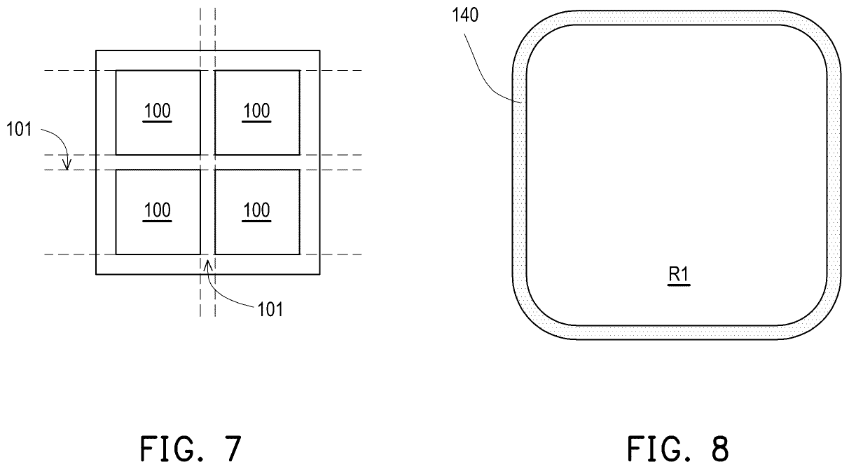

FIG. 1 to FIG. 6 are partial schematic cross-sectional views illustrating a manufacturing method of a substrate according to some embodiments of the disclosure. FIG. 7 is a partial schematic top view of the structure of FIG. 1. FIG. 8 is a partial schematic top view of the structure of FIG. 5.

Referring to FIG. 1, a core layer 110 is provided, wherein the core layer 110 may have a top surface 111 and a bottom surface 112 opposite the top surface 111. For example, the core layer 110 includes the base material layer 113 and a plurality of conductive connectors 114, wherein the base material layer 113 is penetrated through by the conductive connectors 114.

In some implementations, the base material layer 113 may be a glass, such that the conductive connectors 114 may be suitable TGVs, in some implementations, the base material layer 113 may be a ceramic, such that the conductive connectors 114 may be suitable TCVs, but the disclosure is not limited thereto, other suitable materials may be used.

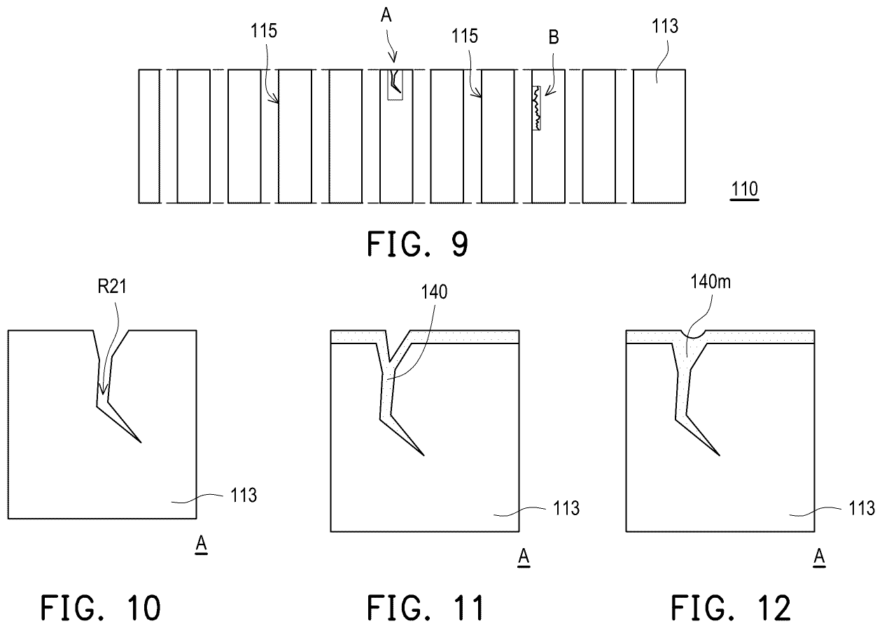

In some embodiments, the base material layer 113 includes a plurality of through vias 115, and the conductive connectors 114 may be formed in the through vias 115, wherein the through vias 115 may be formed by a laser drilling process or other suitable via process. Herein, details of the through vias 115 may be described in FIG. 9 and FIG. 13 to FIG. 15.

In some embodiments, the conductive connectors 114 laterally encapsulated by the base material layer 113 may be made of conductive material(s) such as copper, gold, nickel, aluminum tin, metal alloy, a combination thereof.

In the present embodiment, a first circuit structure 120 is formed on the top surface 111 of the core layer 110 and a second circuit structure 130 is formed on the bottom surface 112 of the core layer 110 respectively, wherein the first circuit structure 120 and the second circuit structure 130 are disposed on two opposite sides of the core layer 110, and the conductive connectors 114 may provide a vertical conductive path between the first circuit structure 120 and the second circuit structure 130. In FIG. 1, the core layer 110 is thicker than the first circuit structure 120 and the second circuit structure 130.

As shown in the enlarge portion of FIG. 1, the first circuit structure 120 and the second circuit structure 130 may be referred to as redistribution structures or build-up structures including dielectric layer and conductive layers. For example, a plurality of first dielectric layers 121 of the first circuit structure 120 and a plurality of second dielectric layers 131 of the second circuit structure 130 are formed by laminating dielectric material (such as PSPI (Photosensitive Polyimide), ABF, PP, or the like) over a formed conductive layer (such as copper or the like) or the core layer 110, and a plurality of first conductive layers 122 of the first circuit structure 120 and a plurality of second conductive layers 132 of the second circuit structure 130 are respectively formed on the first dielectric layers 121 and the second dielectric layers 131. The dielectric layers (e.g., 121, 131) in the build-up structures insulate the conductive layer (e.g., 122, 132), from conductive traces underneath the dielectric layer (e.g., 121, 131). Herein the first circuit structure 120 and the second circuit structure 130 may be formed by suitable processes (such as photolithography, etch, or the like), the disclosure is not limited thereto.

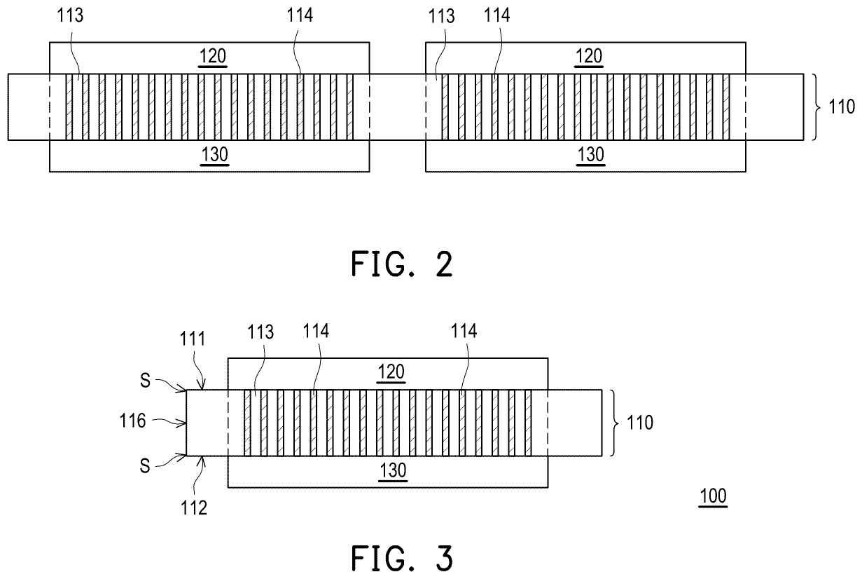

It should be noted that, the above detail description may be not shown in FIG. 2 to FIG. 6 for clarity, the entirety of each of the above-mentioned is hereby incorporated in FIG. 2 to FIG. 6 and made a part of these figures.

In some embodiments, the conductive elements (e.g., conductive patterns, conductive vias, conductive lines, or conductive pads) of the first conductive layers 122 are finer than the conductive elements (e.g., conductive patterns, conductive vias, conductive lines, or conductive pads) of the second conductive layers 132, thereby chip may be bonded on the first circuit structure 120 and external terminals may be bonded on the second circuit structure 130 (not shown), but the disclosure is not limited thereto. In some embodiments, the contact density of the first circuit structure 120 is denser than the contact density of the second circuit structure 130, the disclosure is not limited thereto.

Referring to FIG. 1 and FIG. 7, in the present embodiment, a plurality of substrate units 100 are provided and a plurality of scribe lines 101 are located between the substrate units 100 for separation, that is to say, the structure 10 is a wafer form or panel form. For example, size of the wafer size or panel may be 510 mm×515 mm and size of each of substrate units 100 may be 200 mm×200 mm, but the disclosure is not limited thereto.

Referring to FIG. 2, the first circuit structure 120 and the second circuit structure 130 may be patterned by suitable processes. For example, portions of the dielectric layer (e.g., 121, 131) and the conductive layer (e.g., 122, 132) may be removed by mechanical grinding process, laser process, or the like, such that portions of the top surface 111 of the core layer 110 and portions of the bottom surface 112 of the core layer 110 may be exposed.

Referring to FIG. 3, a singulation process (such as laser process, dicing saw cut process, or the like) is performed to form each of the substrate units 100, wherein each of the substrate units 100 may include the core layer 110 including the base material layer 113, the conductive connectors 114, the first circuit structure 120, and the second circuit structure 130. Herein, the number of the substrate units 100 formed by the singulation process may be determined according to actual design requirements. And then, after singulation process, a side surface 116 of the core layer 110 may be formed between the top surface 111 and the bottom surface 112 of the core layer 110. On the other hand, a plurality of intersection points S between the side surface 116 and the top surface 111 or the side surface 116 and the bottom surface 112 may be sharped edges.

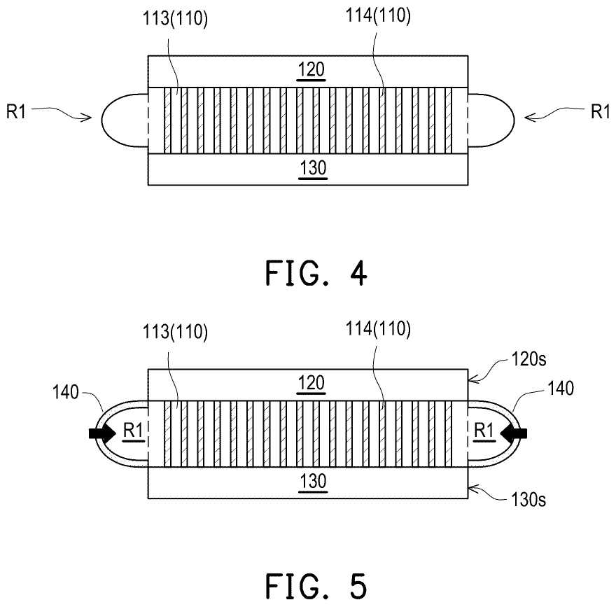

Referring to FIG. 4, the aforementioned sharped edges may reduce the reliability of the substrate, thereby a trimming process is performed to form rounded edge portion R1 (also can be recessed and rounded edge portion) of the core layer 110 located between the top surface 111 and the bottom surface 112. In some embodiments, portions of the base material layer 113 exposed by the first circuit structure 120 and the second circuit structure 130 may be removed by grinding to make chamfer at the edge of core layer 110, but the disclosure is not limited thereto. In some embodiments, the rounded edge portion R1 may be protruded from the first circuit structure 120 and the second circuit structure 130, but the disclosure is not limited thereto.

Referring to FIG. 5, a deposition process is performed on the rounded edge portion R1 to form a first protection layer 140, by doing so, the rounded edge portion R1 is compressed by the first protection layer 140 (as shown by the arrow in FIG. 5) at cooling state, and the first protection layer 140 may be directly in contact with the rounded edge portion R1, thereby cracks of the core layer 110 introduced in the above process (such as singulation process, grinding process, or the like) may be suppressed, the probability of propagation may be reduced which may improve reliability of a subsequent product. In some embodiments, the deposition process includes sputtering, CVD, or ALD. Herein, the compression stress remains since the operation temperature of a typical HPC system is below 80° C. Hence, the reliability of the substrate is maintained.

In some embodiments, a coefficient of thermal expansion (CTE) of a material of the first protection layer 140 is higher than a coefficient of thermal expansion of a material of the core layer 110, thereby the suppressed effect may be more significant, for example, the material of the first protection layer 140 includes metal oxides or metal nitride, such as alumina (CTE is 7.2 ppm), alumina nitride (CTE is 5.3 ppm) or stainless steel, which has a high CTE that the underneath glass.

Inorganic material and the material of the core layer 110 includes glass or ceramic, but the disclosure is not limited thereto. For example, while cooling from the 200° C. to room temperature, the CTE difference of alumina and glass will give glass a compression stress which assuming it is stress-free during the deposition temperature of the alumina, but the disclosure is not limited thereto.

In one embodiment, the material of the base material layer 113 is glass having many benefits such as high temperature stability, less warpage, high density of TGV, surface flatness, fine line possibility, potential large format, and low cost or the like, however, the crack issue in glass (brittle material) is more serious, therefore, the first protection layer 140 used in a glass core substrate may have superiority, but the disclosure is not limited thereto.

Referring to FIG. 5 and FIG. 8, the first protection layer 140 is conformally formed on the rounded edge portion R1, for example, entire exposed surface of the rounded edge portion R1 may be covered by the first protection layer 140. In the present embodiment, the first protection layer 140 may be not covered a side surface 120s of the first circuit structure 120 and a side surface 130s the second circuit structure 130, but the disclosure is not limited thereto.

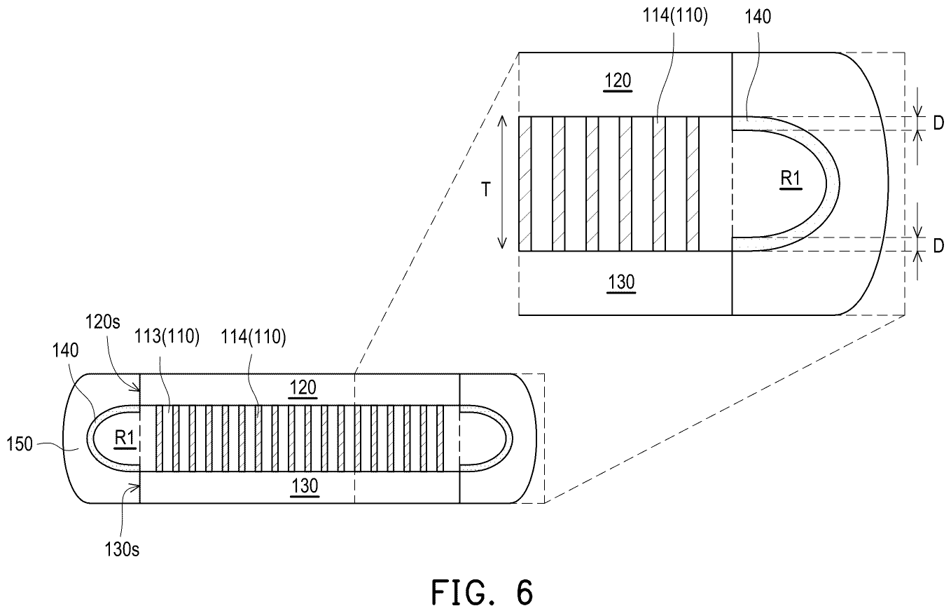

Referring to FIG. 6, the first protection layer 140 is encapsulated by a second protection layer 150, such that the first protection layer 140 is enclosed by the second protection layer 150. The second protection layer 150 may provide a buffer function, for example, impact or stress imposed to the substrate may be absorbed, the reliability may be further improved, but the disclosure is not limited thereto, the second protection layer 150 may be omitted in the unillustrated embodiments.

In some embodiments, a material of the second protection layer 150 may include polymer (organic material) which different from the first protection layer 140 (inorganic material), for example, the material of the second protection layer 150 may include silicone-based material, epoxy coating materials, or other suitable soft materials, the disclosure is not limited thereto.

In some embodiments, the second protection layer 150 covers the side surface 120s of the first circuit structure 120 and the side surface 130s the second circuit structure 130, meanwhile the rounded edge portion R1 and the first protection layer 140 are entirely wrapped by the second protection layer 150, but the disclosure is not limited thereto.

In FIG. 6, the first protection layer 140 includes a tapered portion relative to a thickness T of the core layer 110 corresponding to size D. In some embodiments, size D of the tapered portion of first protection layer 140 may be smaller than 5 micrometers (μm) or other suitable value, but the disclosure is not limited thereto, the tapered portion may be omitted in the unillustrated embodiments.

It is to be noted that the following embodiments use the reference numerals and a part of the contents of the above embodiment, and the same or similar reference numerals are used to denote the same or similar elements, and the description of the same technical content is omitted. For the description of the omitted part, reference may be made to the above embodiments, and details are not described in the following embodiments.

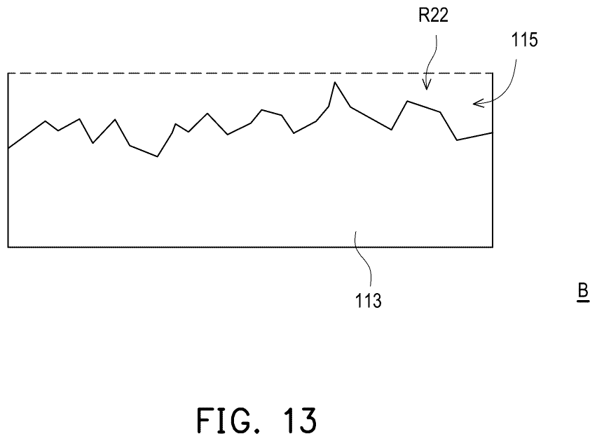

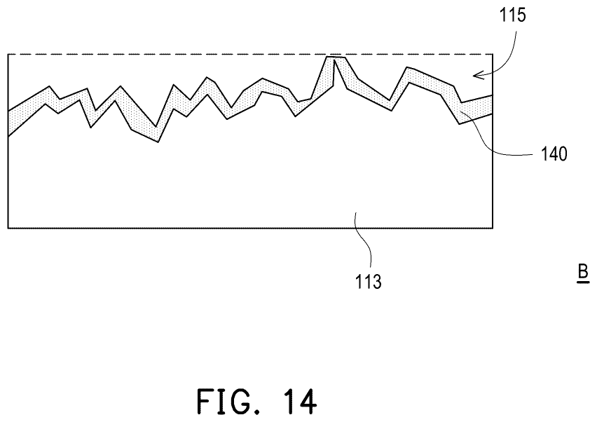

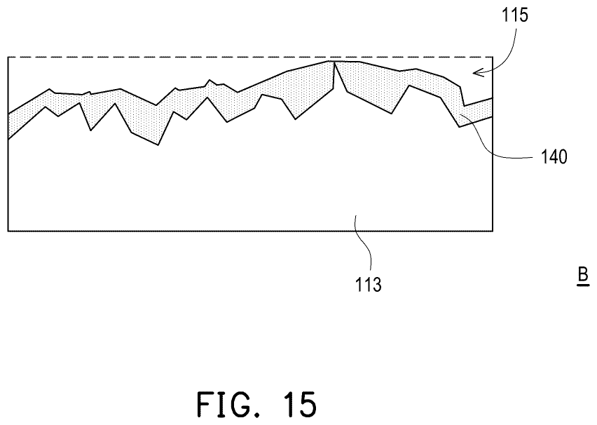

FIG. 9 is partial schematic cross-sectional view illustrating a core layer of a substrate according to some embodiments of the disclosure. FIG. 10 and FIG. 13 are partial schematic enlarge view of the structure of FIG. 10. FIG. 11 and FIG. 12 are partial schematic cross-sectional views illustrating a manufacturing method of a core layer of a substrate according to some embodiments of the disclosure following by FIG. 10. FIG. 14 and FIG. 15 are partial schematic cross-sectional views illustrating a manufacturing method of a core layer of a substrate according to some embodiments of the disclosure following by FIG. 13.

According to property of the material, the glass transition temperature (Tg) of glass is higher than the glass transition temperature of organic material, therefore the glass core substrate may be process and operate at a higher temperature, for example, the organic core substrate may only operate at temperature below 250° C., and the glass core substrate may operate exceed 400° C. In addition, the organic core substrate with fiberglass, fillers, etc., such that the surface is not flat, and making fine lines on top of the organic substrate is very challenge significantly below 10 ums, in contrast, the surface roughness (Ra) of the glass may be as smooth down to a few nanometers, thereby making fine lines on top of the glass core substrate is easier. Moreover, the organic core substrate may be limited to size around 500 mm, and glass core substrate may be cost effect for bigger format process, in some embodiments, glass core substrate can be with large format 1000 mm is feasible. based on these advantages, the glass core layer 110 (not organic core substrate) is more competitive.

However, in glass core substrate, cracks may be existed in different edge portions, for example, cracks may be existed in outer side surface 116 of the core layer 110 as shown in the above embodiment, and cracks may also be existed in a top surface and an inner side surface of the core layer 110 in the following embodiment, therefore, the protection layer 140 may be applied at outer side surface 116, top surface 111 and an inner side surface (such as sidewalls of the through vias 115), or a combination thereof.

Referring to FIG. 9, in this embodiment, after drilling process, the glass core layer 110 has a plurality of rough edge portions (also can refer as rough portion), for example, the rough edge portions include a top surface rough edge portion R21 (as shown in frame A, also can refer as top surface rough portion) on the top surface 111 and an inner side surface rough edge portion R22 (as shown in frame B, also can refer as inner side surface rough portion) in the through vias 115. It should be noted that one of the top surface rough edge portion R21 and the inner side surface rough edge portion R22 may be omitted.

Referring to FIG. 10 to FIG. 11, the protection layer 140 may be formed on the top surface rough edge portion R21, and the protection layer 140 is disposed on and directly in contact with the top surface rough edge portion R21, wherein a coefficient of thermal expansion of a material of the protection layer 140 is higher than a coefficient of thermal expansion of a material of the glass core layer 110. By doing so, a roughness of a surface of the protection layer 140 is less than a roughness of the top surface rough edge portion R21, therefore, the s top surface rough edge portion R21 may be repaired. Using the protection layer 140 may smooth and patch the cracks to achieve lower surface roughness. Herein, a material of the protection layer 140 includes inorganic material (such as SiO₂, Al₂0₃, Si₃N₄) or organic material (such as polyimide of parylene). Even the CTE of SiO₂ and Si₃N₄ may less than the CTE of the glass core, but it also can be used to improve the reliability of the glass core to certain extend.

Referring to FIG. 11 to FIG. 12, alternatively, an annealing process (such as a reflow process is operated at about 400° C.) is performed on the protection layer 140 to form smoother protection layer 140m before forming the conductive connectors 114 alternatively, by doing so, spaces of the top surface rough edge portion R21 are filled up with the smoother protection layer 140m, but the disclosure is not limited thereto, the annealing process is optional. It should be noted that, the annealing process may be used in FIG. 5 according to design requirement.

Referring to FIG. 13 to FIG. 15, similar to FIG. 10 to FIG. 12, in this section, the protection layer 140 may be formed on the inner side surface rough edge portion R22, and the protection layer 140 is disposed on and directly in contact with the inner side surface rough edge portion R22 and the reflow process is performed, thereby the inner side surface rough edge portion R22 may be repaired, and a good signal quality is ensured to make high-frequency signal conducting through the surface of conductive connectors 114, but the disclosure is not limited thereto.

To sum up, cracks of the core layer may be suppressed by the protection layer, thereby the probability of propagation may be reduced which may improve reliability of a subsequent product.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A substrate, comprising:
a core layer, comprising a top surface, a bottom surface, and a rounded edge located between the top surface and the bottom surface;
a first circuit structure, disposed on the top surface;
a second circuit structure, disposed on the bottom surface; and
a first protection layer, disposed on and directly in contact with the rounded edge portion; and
a second protection layer, wherein the first protection layer is enclosed by the second protection layer.

2. The substrate according to claim 1, wherein the material of the first protection layer comprises alumina, alumina nitride, or stainless steel.

3. The substrate according to claim 1, wherein the material of the core layer comprises glass or ceramic.

4. The substrate, according to claim 1, wherein the rounded edge portion protrudes from the first circuit structure and the second circuit structure.

5. The substrate according to claim 1, wherein the first protection layer comprises a-tapered portion relative to a thickness of the core layer.

6. The substrate according to claim 1, wherein a coefficient of thermal expansion of a material of the first protection layer is higher than the coefficient of thermal expansion of a material of the core layer.

7. The substrate according to claim 1, wherein a material of the second protection layer comprises polymer.

8. The substrate according to claim 1, wherein the second protection layer covers sidewalls of the first circuit structure and sidewalls of the second circuit structure.

9. The substrate according to claim 1, wherein the rounded edge portion and the first protection layer are entirely wrapped by the second protection layer.

10. A manufacturing method of a substrate, comprising:
providing a core layer;
forming a first circuit structure on a top surface of the core layer;
forming a second circuit structure on a bottom surface of the core layer;
patterning the first circuit structure and the second circuit structure;
forming a rounded edge portion between the top surface and the bottom surface of the core layer; and
performing a deposition process on the rounded edge portion to form a first protection layer, wherein the rounded edge portion is compressed by the first protection layer.

11. The manufacturing method of substrate according to claim 10, wherein the deposition process comprises sputtering, CVD process or ALD process.

12. The manufacturing method of substrate according to claim 10, wherein forming a rounded edge portion further comprising: performing a grinding process.

13. The manufacturing method of substrate according to claim 10, further comprising: performing a singulation process between patterning the first circuit structure and the second circuit structure and forming a rounded edge portion.

14. The manufacturing method of substrate according to claim 10, wherein the first protection layer is conformally formed on the rounded edge portion.

15. The manufacturing method of substrate according to claim 10, further comprising:
encapsulating the first protection layer by a second protection layer.

16. The manufacturing method of substrate according to claim 10, wherein performing an annealing process on the first protection layer.

17. A substrate, comprising:
a glass core layer, comprising a plurality of rough portions; and
a protection layer, disposed on and directly in contact with the plurality of rough portions, wherein a coefficient of thermal expansion of a material of the protection layer is higher than a coefficient of thermal expansion of a material of the glass core layer.

18. The substrate according to claim 17, wherein the plurality of rough portions comprises a top surface rough edge portion, an inner side surface rough edge portion, or a combination thereof.

19. The substrate according to claim 17, wherein a roughness of a surface of the protection layer is less than a roughness of the rough portions.

20. The substrate according to claim 17, wherein a material of the protection layer comprises inorganic material or organic material.
